(19) United States
(12) Patent Application Publication
(10) Pub. No.: US 2011/0308560 A1
(43) Pub. Date: Dec. 22, 2011

(54) TEMPERATURE AND FLOW CONTROL OF EXHAUST GAS FOR THERMOELECTRIC UNITS

(76) Inventors: Ivan Arbuckle, Columbus, IN (US); Kwin Abram, Columbus, IN (US); Joseph E. Callahan, Greenwood, IN (US); Michael D. Virtue, Seymour, IN (US); James Egan, Indianapolis, IN (US); Robin Willats, Columbus, IN (US); Thorsten Keeser, Augsburg (DE)

(21) Appl. No.: 13/203,307

(22) PCT Filed: Feb. 12, 2010
(86) PCT No.: PCT/US10/23993

§ 371 Date: Aug. 25, 2011

Related U.S. Application Data
(60) Provisional application No. 61/155,633, filed on Feb. 26, 2009.

(51) Int. Cl. F01N 5/02; H01L 35/30

(52) U.S. Cl. 136/205; 60/320; 60/324

(57) ABSTRACT

A vehicle exhaust system includes an exhaust pipe that provides heated exhaust gases to a thermoelectric unit as an input. A temperature control mechanism ensures that exhaust gas is directed into the thermoelectric unit only if the exhaust gas is within a specified temperature range. The thermoelectric unit transforms the exhaust gas heat into electrical power.

### RELATED APPLICATION

This application is the U.S national phase of PCT/US2010/023993 which was filed Feb. 12, 2010, and which claims priority to U.S. Provisional Application No. 61/155,633, which was filed Feb. 26, 2009.

### TECHNICAL FIELD

This invention generally relates to a system configuration to control temperature and flow of exhaust gases into a thermoelectric unit in a vehicle exhaust system.

### BACKGROUND OF THE INVENTION

A thermoelectric unit comprises an energy recovery device that transforms waste exhaust heat from an exhaust system into electrical power that can be stored and used for other vehicle systems. This can improve fuel economy and increase operating efficiencies for many vehicle systems.

Thermoelectric units comprise a box-shaped components with flat contact surfaces to ensure the most effective flow of heat possible. Such a shape is often difficult to integrate into a vehicle exhaust system due to packaging constraints and connection interfaces that may not include square cross-sections.

Further, thermoelectric units are constructed from semi-conductor and semi-metal materials that have specific upper and lower temperature limits of efficient operation. Exposure to significantly high exhaust gas temperatures in excess of this upper limit can damage these materials. Also, exhaust gas temperatures that are below the lower limit can result in ineffective and insufficient electrical power generation.

### SUMMARY OF THE INVENTION

A vehicle exhaust system includes an exhaust pipe that provides heated exhaust gases to a thermoelectric unit as an input. A temperature control mechanism ensures that exhaust gas is directed into the thermoelectric unit only if the exhaust gas is within a specified temperature range. The thermoelectric unit then transforms the exhaust gas heat into electrical power.

In one example, the exhaust pipe has at least one portion with a polygonal cross-section. The thermoelectric unit is comprised of a plurality of TEG modules that each have a flat mounting surface positioned on the portion of the exhaust pipe that has the polygonal cross-section.

In one example, a polygonal portion of the exhaust pipe is formed by hydro-forming. In another example, the polygonal portion is provided by attaching a polygonal pipe to a circular pipe with a connecting element.

In one example, electrical power generated by the thermoelectric unit is stored in a storage device and is subsequently used to power at least one vehicle system.

In one example, the thermoelectric unit comprises a non-bypass configuration and includes a cooling device that is positioned upstream of the thermoelectric device. The cooling device cools heated exhaust gases to maintain temperature levels within the specified temperature range.

In one example, the thermoelectric unit comprises a primary exhaust gas flow path. A bypass is provided that includes a bypass pipe having one end connected to the exhaust pipe upstream of the thermoelectric unit and an opposite end connected to the exhaust pipe downstream of the thermoelectric unit. At least one electrically controlled valve is located in the primary exhaust gas flow path to direct exhaust gas through the bypass under predetermined temperature conditions. At least one temperature sensor is positioned within the primary exhaust gas flow path upstream of the at least one electrically controlled valve to measure an exhaust gas temperature prior to entering the thermoelectric unit. This measured temperature is communicated to a controller that determines if the measured exhaust gas temperature is within the specified temperature range. A control signal is generated to close the primary exhaust gas flow path with the electrically controlled valve and such that exhaust gas is directed into the bypass when the measured exhaust gas temperature exceeds an upper limit of the specified temperature range.

These and other features of the present invention can be best understood from the following specification and drawings, the following of which is a brief description.

### BRIEF DESCRIPTION OF THE DRAWINGS

FIG. 1 is a schematic representation of one example of an exhaust pipe with a thermoelectric unit.

FIG. 2A is a schematic representation of another example of an exhaust pipe with a thermoelectric unit.

FIG. 2B is a schematic representation of another example of an exhaust pipe with a thermoelectric unit.

FIG. 3A is a top perspective view of one example of a thermoelectric unit mounted on a polygonal pipe portion.

FIG. 3B is a bottom perspective view of the thermoelectric unit of FIG. 3A.

FIG. 4 is a perspective view of a hydro-formed polygonal pipe portion.

FIG. 5 is a perspective end view of polygonal pipes to be attached to an exhaust pipe.

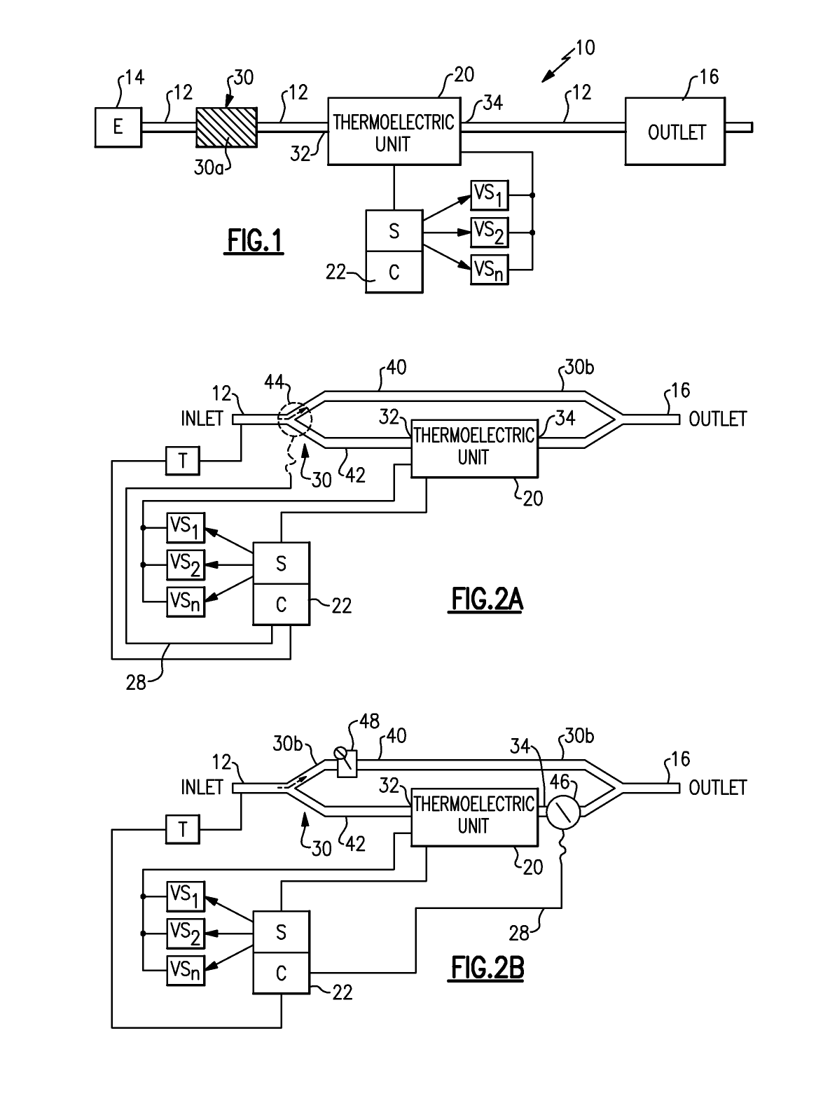

### DETAILED DESCRIPTION OF THE PREFERRED EMBODIMENT

A vehicle exhaust system 10, shown in FIG. 1, includes an exhaust pipe 12 that directs heated exhaust gases from an internal combustion engine 14 to an exhaust system outlet 16, which can comprise a tailpipe, for example. FIG. 1 is highly schematic and it should be understood that the exhaust system 10 can include additional exhaust components and pipes positioned between the engine 14 and the outlet 16. These additional components could include mufflers, resonators, catalysts, etc., for example.

A thermoelectric unit 20 is associated with the exhaust pipe 12 to transform heat generated by exhaust gases into electrical energy/power. The thermoelectric unit 20 can store this generated power in a storage device S, which cooperates with a controller 22 to provide the stored power to various vehicle systems VS1-VSn as needed. Optionally, the thermoelectric unit 20 can communicate the generated power directly to the vehicle systems VS1-VSn. The power can be used for any type of vehicle system such as engine controls, exhaust system controls, a door lock system, window lifting mechanism, interior lighting, etc., for example.

In one example, the thermoelectric unit 20 is constructed from at least one of semi-conductor and semi-metal materials that have specific upper and lower temperature limits of efficient operation. Exposure to excessively high exhaust gas temperatures over this upper limit can damage these materials, and exhaust gas temperatures that are below the lower limit can result in ineffective electrical power generation.

In one example shown in FIG. 1, a temperature control device 30 is positioned upstream of the thermoelectric unit 20. In this example, the temperature control device 30 comprises a cooling device 30a that cools heated exhaust gases to temperatures within a specified temperature range that is between the upper and lower temperature limits of materials used to construct the thermoelectric unit 20. These cooled exhaust gases are then communicated to an inlet 32 to the thermoelectric unit 20. The exhaust gases pass through the thermoelectric unit 20, waste heat from the exhaust gases is transformed into electrical energy, and then the gases exit the thermoelectric unit 20 via an outlet 34. This configuration comprises a non-bypass arrangement where all of the exhaust gases flow through the thermoelectric unit 20.

The cooling device 30a can comprise many different types of cooling components. For example, the cooling device 30a could be a fluid cooled heat exchanger, or could include air or water injection for cooling. Optionally, the cooling device 30a could comprise an air gap pipe combined with air injection or forced air cooling. The air gap pipe as an air-to-air heat exchanger provides both cooling and also a potential reduction in thermal inertia to avoid faster heat up.

One advantage with the configuration shown in FIG. 1 is the avoidance of a bypass configuration and associated controls. Further, this configuration provides the ability to maximize electrical output of the thermoelectric unit 20 by maintaining exhaust gas within an optimum temperature operating range.

In another example, the temperature control device 30 can comprise a bypass 30b including a bypass pipe 40 and at least one valve. A bypass configuration allows exhaust gas to be diverted around the thermoelectric unit 20 as gas temperatures increase. The bypass pipe 40 has one pipe end fluidly connected to the exhaust pipe 12 upstream of the thermoelectric unit 20 and an opposite pipe end fluidly connected to the exhaust pipe 12 downstream of the thermoelectric unit 20. Along the primary path, exhaust gas flows through the exhaust pipe 12 enters the thermoelectric unit 20 through an inlet pipe portion 42 and exits the thermoelectric unit to proceed to the outlet 16. Along the bypass, exhaust gases flow through the bypass pipe 40, i.e. around the thermoelectric unit 20, and then flow to the outlet 16.

In one example configuration, the bypass configuration includes a three-way valve 44 positioned upstream of the thermoelectric unit 20. The three-way valve 44 is positioned at a Y-split between the exhaust pipe 12 entering the thermoelectric unit 20 and the bypass pipe 40 directing exhaust gases around the thermoelectric unit 20. The three-way valve 44 comprises an electrically actuated single valve that has a single inlet from the exhaust pipe, and two outlets. One outlet is to the thermoelectric unit 20 and the other outlet is to the bypass pipe 40.

A temperature sensor T is positioned in the primary exhaust path upstream from the three-way valve 44. The temperature sensor T measures a temperature of the exhaust gases upstream of the thermoelectric unit 20 and communicates this information to the controller 22. If the measured temperature exceeds the upper limit of the specified temperature range, the controller 22 generates a control signal 28 to actuate the valve 44 to close the primary exhaust gas path and direct the exhaust gases into the bypass.

If the measured temperature is within the specified range, the controller 22 issues a control signal 28 to actuate the valve 44 to close the bypass such that all exhaust gas flows through the primary exhaust path and into the thermoelectric unit 20. As discussed above, the thermoelectric unit 20 then converts the heat into power which can be stored in a storage device S, or communicated directly to various vehicle systems VS1-VSn as needed.

One disadvantage with this type of valve configuration is that the three-way valve that controls flow split between the bypass and the thermoelectric unit 20 is expensive and is required to be positioned at the Y-split. Further, this type of configuration may lead to increased tailpipe noise when the vehicle exhaust system 10 is operating in a bypass mode.

A more advantageous configuration utilizes two separate valves instead of using the three-way valve 44. A first valve 46 comprises an electrically actuated single valve that is positioned downstream of the outlet 34 of the thermoelectric unit 20 in the primary exhaust path, i.e. is positioned in a thermo-electric leg of the system. This first valve 46 comprises a controlled valve having a single inlet and a single outlet with movement being controlled by the controller 22. A second valve 48 is positioned within the bypass pipe 40. This second valve 48 comprises an adaptive throttling valve that is solely responsive to exhaust gas flow through the bypass leg of the system. In one example, the second valve 48 comprises a spring-loaded passive valve.

The temperature sensor T is positioned in the primary exhaust path upstream from the thermoelectric unit 20. The temperature sensor T measures a temperature of the exhaust gases and communicates this information to the controller 22. If the measured temperature exceeds the upper limit of the specified temperature range, the controller 22 generates a control signal 28 to actuate the valve 46 to close the primary exhaust gas path and direct the exhaust gases into the bypass 30b.

If the measured temperature is within the specified range, the controller 22 issues a control signal to move the valve 46 to an open position such that exhaust gas is allowed to flow through the primary exhaust path and into the thermoelectric unit 20. As discussed above, the thermoelectric unit 20 then converts the heat into power which can be stored in a storage device S, or communicated directly to various vehicle systems VS1-VSn as needed. The second valve 48 in the bypass opens and closes based on the pressure of exhaust gas flow as known.

One advantage with this configuration is that packaging of the system is more flexible because valve position is not tied to a Y-split. Further, the second valve 48, i.e. the adaptive valve, provides acoustic benefit in a bypass mode. Also, this configuration allows usage of the thermoelectric unit 20 and associated inlet pipe as an acoustic tuning element in conditions where there is no flow through the thermoelectric unit 20 to benefit exhaust noise in a by-pass mode. Positioning of the first valve 46 downstream of the thermoelectric unit 20 reduces the temperature exposure of the valve, reducing the necessary temperature capability of the valve, thus reducing cost. Also, the types of valves in this system are more readily available and are lower cost.

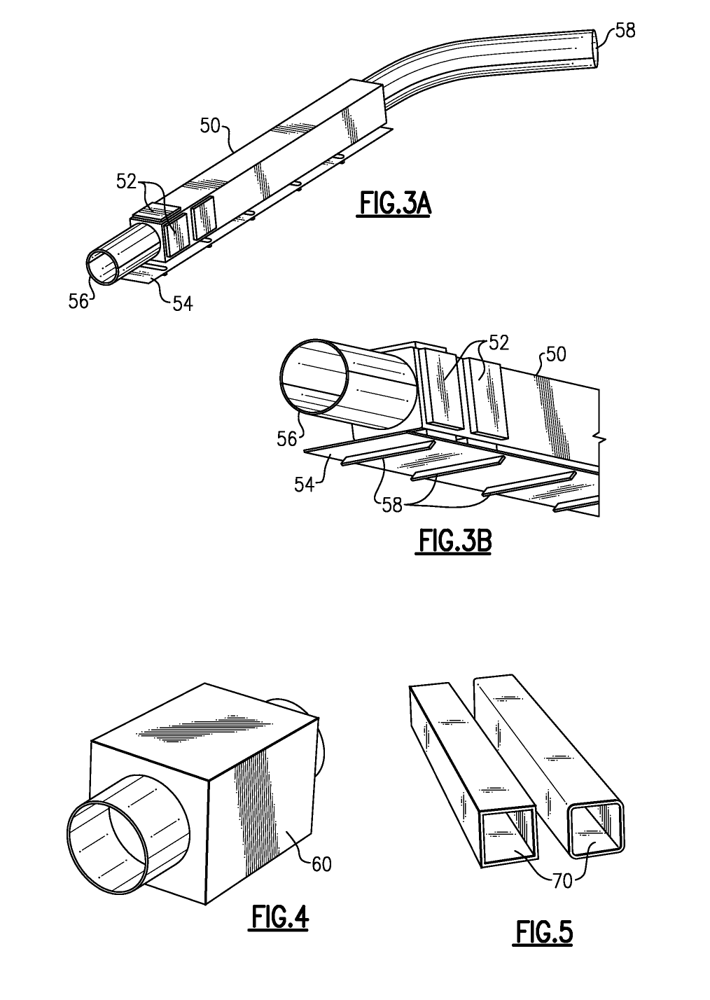

As shown in FIGS. 3A and 3B, the thermoelectric unit 20 utilizes modules 52 that typically have a polygonal shape with a flat mounting surface. In one example, the modules 52 comprise a square shape. These modules 52 need a flat contact surface within the exhaust system to ensure the most efficient flow of heat possible. The exhaust pipe 12 is configured to provide flat areas for the modules 52.

The exhaust pipe 12 is configured to have a polygonal portion that receives exhaust gas via an inlet 56 and communicates the exhaust gas to an outlet 58. A shield and ventilation plate 54 with cooling fins 58 (FIG. 3B) can be mounted to this polygonal portion to provide additional cooling as needed.

In one example (FIG. 4), the exhaust pipe 12 includes a portion 60 that is formed to have a polygonal cross-section. This formation is accomplished by hydro-forming, for example. A high water pressure is introduced inside the pipe 12 causing the pipe to expand and take the shape of a die surrounding the pipe 12. This hydro-forming process would occur subsequent to any bending operations that need to be performed on the pipe 12.

In another example (FIG. 5), a polygonal pipe 70, such as a pipe 70 having a square cross-section, is installed at a location within the exhaust pipe 12 which is defined by a curved outer surface. The square ends of the pipe 70 can be connected to circular pipes using cones or other types of connection attachments. Welding or brazing can be used to secure the cones or other connecting elements in place. The modules 52 can then be mounted to a flat outer surface of the pipe 70.

Although a preferred embodiment of this invention has been disclosed, a worker of ordinary skill in this art would recognize that certain modifications would come within the scope of this invention. For that reason, the following claims should be studied to determine the true scope and content of this invention.

What is claimed is:

1. A vehicle exhaust system comprising:
an exhaust pipe to conduct exhaust gases from an internal combustion engine to an exhaust system outlet;
a thermoelectric unit receiving exhaust gas heat from said exhaust pipe as an input, said thermoelectric unit transforming said exhaust gas heat into electrical power; and
a temperature control device upstream of said thermoelectric unit to ensure that a temperature of said exhaust gas is entering said thermoelectric unit within a specified temperature range.

2. The vehicle exhaust system according to claim 1 wherein said thermoelectric unit includes at least one module comprised of a semi-conductor or semi-metal material that has an upper temperature limit and a lower temperature limit, said specified temperature range being defined as a range between said lower temperature limit and said upper temperature limit.

3. The vehicle exhaust system according to claim 1 wherein said temperature control device comprises a cooling device having an inlet receiving heated exhaust gas from said exhaust pipe and an outlet that directs cooled exhaust gas to an inlet of said thermoelectric unit.

4. The vehicle exhaust system according to claim 3 wherein said cooling device comprises at least one of a heat exchanger, an injection cooler, or an air gap pipe.

5. The vehicle exhaust system according to claim 3 wherein said thermoelectric unit comprises a non-bypass configuration with all upstream exhaust gas flow entering said inlet of said thermoelectric unit and subsequently exiting from an outlet of said thermoelectric unit.

6. The vehicle exhaust system according to claim 1 wherein said thermoelectric unit is positioned within a primary exhaust gas flow path, and wherein said temperature control device comprises a bypass including a bypass pipe having one end connected to said exhaust pipe upstream of said thermoelectric unit and an opposite end connected to said exhaust pipe downstream of said thermoelectric unit, and including at least one valve to direct exhaust gas through said bypass under predetermined temperature conditions.

7. The vehicle exhaust system according to claim 6 wherein said at least one valve comprises a single valve having a single inlet receiving input from said exhaust pipe and a first outlet directing exhaust gas flow into said bypass pipe when said temperature of said exhaust gas exceeds said specified temperature range and a second outlet directing exhaust gas flow into said thermoelectric unit when said temperature of said exhaust gas is within said specified temperature range.

8. The vehicle exhaust system according to claim 7 wherein said single valve comprises an electrically actuated valve.

9. The vehicle exhaust system according to claim 6 wherein said at least one valve comprises an adaptive valve positioned within said bypass pipe and a controlled valve positioned within said exhaust pipe downstream of said thermoelectric unit.

10. The vehicle exhaust system according to claim 9 wherein said adaptive valve comprises a spring-loaded passive valve solely responsive to exhaust gas flow and said controlled valve comprises an electrically actuated valve having a single inlet and a single outlet.

11. The vehicle exhaust system according to claim 6 including at least one temperature sensor positioned within said primary exhaust gas flow path upstream of said at least one valve to measure an exhaust gas temperature prior to entering said thermoelectric unit, and wherein measured exhaust gas temperature is communicated to a controller that determines if said measured exhaust gas temperature is within said specified temperature range, and wherein said controller generates a control signal to close said primary exhaust gas flow path and direct exhaust gas into said bypass when said measured exhaust gas temperature exceeds an upper limit of said specified temperature range.

12. The vehicle exhaust system according to claim 1 wherein said exhaust pipe includes at least one portion having a polygonal cross-section, said thermoelectric unit being positioned at said polygonal cross-section.

13. The vehicle exhaust system according to claim 12 wherein said portion having said polygonal cross-section comprises a square tube connected to said exhaust pipe.

14. The vehicle exhaust system according to claim 12 wherein said portion having said polygonal cross-section comprises a hydro-formed portion of said exhaust pipe.

15. The vehicle exhaust system according to claim 12 wherein said thermoelectric unit comprises a plurality of thermoelectric generator (TEG) modules each having a flat mounting surface that is positioned on an exterior surface of said portion having a polygonal cross-section.

16. A vehicle exhaust system comprising:
an exhaust pipe having a curved outer surface;
a thermoelectric unit receiving exhaust gas heat from said exhaust pipe as an input, said thermoelectric unit transforming said exhaust gas heat into electrical power, and wherein said thermoelectric unit comprises a plurality of thermoelectric generator (TEG) modules each having a flat mounting surface; and
wherein said exhaust pipe includes at least one portion with a polygonal cross-section, said plurality of thermoelectric generator (TEG) modules of said thermoelectric unit being positioned at said polygonal cross-section.

17. The vehicle exhaust system according to claim 16 wherein said at least one portion with said polygonal cross-section comprises one of a square tube connected to said exhaust pipe or a hydro-formed portion of said exhaust pipe.

18. The vehicle exhaust system according to claim 16 including a temperature control device upstream of said thermoelectric unit to ensure that a temperature of said exhaust gas is entering said thermoelectric unit within a specified temperature range.

19. The vehicle exhaust system according to claim 18 wherein said thermoelectric unit comprises a non-bypass configuration with all upstream exhaust gas flow entering an inlet of said thermoelectric unit and subsequently exiting from an outlet of said thermoelectric unit, and wherein said temperature control device comprises a cooling device having an inlet receiving heated exhaust gas from said exhaust pipe and an outlet that directs cooled exhaust gas to said inlet of said thermoelectric unit

20. The vehicle exhaust system according to claim 18 wherein said thermoelectric unit is positioned within a primary exhaust gas flow path, and wherein said temperature control device comprises a bypass including a bypass pipe having one end connected to said exhaust pipe upstream of said thermoelectric unit and an opposite end connected to said exhaust pipe downstream of said thermoelectric unit, and including at least one electrically controlled valve to direct exhaust gas through said bypass under predetermined temperature conditions, and
including at least one temperature sensor positioned within said primary exhaust gas flow path upstream of said at least one electrically controlled valve to measure an exhaust gas temperature prior to entering said thermoelectric unit, and wherein measured exhaust gas temperature is communicated to a controller that determines if said measured exhaust gas temperature is within said specified temperature range, and wherein said controller generates a control signal to close said primary exhaust gas flow path and direct exhaust gas into said bypass when said measured exhaust gas temperature exceeds an upper limit of said specified temperature range.

21. The vehicle exhaust system according to claim 16 wherein electrical power that is generated by transforming exhaust gas heat is stored in a storage device that cooperates with a controller to provide stored power to at least one vehicle system.

22. A method of transforming exhaust gas heat from a vehicle exhaust system into electrical power comprising the steps of:
(a) conducting heated exhaust gas through an exhaust pipe to a thermoelectric unit;
(b) directing exhaust gas into the thermoelectric unit only if the exhaust gas entering the thermoelectric unit is within a specified temperature range; and
(c) transforming exhaust gas heat into electrical power with the thermoelectric unit.

23. The method according to claim 22 including storing the electrical power generated in step (c) in a storage device and using the electrical power to power at least one vehicle system.

24. The method according to claim 22 wherein step (b) includes providing the thermoelectric unit as a non-bypass configuration, positioning a cooling device upstream of the thermoelectric device, and cooling heated exhaust gases to be less than an upper temperature limit of the specified temperature range.

25. The method according to claim 22 wherein step (b) includes
providing the thermoelectric unit as a primary exhaust gas flow path,
providing a bypass that includes a bypass pipe having one end connected to the exhaust pipe upstream of the thermoelectric unit and an opposite end connected to the exhaust pipe downstream of the thermoelectric unit,
locating at least one electrically controlled valve in the primary exhaust gas flow path to direct exhaust gas through the bypass under predetermined temperature conditions,
positioning at least one temperature sensor within the primary exhaust gas flow path upstream of the at least one electrically controlled valve,
measuring an exhaust gas temperature prior to entering the thermoelectric unit,
communicating a measured exhaust gas temperature to a controller that determines if the measured exhaust gas temperature is within the specified temperature range, and
generating a control signal to close the primary exhaust gas flow path with the electrically controlled valve and direct exhaust gas into the bypass when the measured exhaust gas temperature exceeds an upper limit of the specified temperature range.

26. The method according to claim 22 including providing the exhaust pipe to have at least one portion with a polygonal cross-section and mounting the thermoelectric unit on the portion with the polygonal cross-section, and wherein the polygonal cross-section is provided by one of hydro-forming the exhaust pipe or connecting the exhaust pipe to a polygonal pipe.
